(19) United States
(12) Patent Application Publication
(10) Pub. No.: US 2021/0325473 A1
(43) Pub. Date: Oct. 21, 2021

(54) Method for Detecting At Least One Open-Circuit Voltage of a High-Voltage Store

(71) Applicant: Bayerische Motoren Werke Aktiengesellschaft, Muenchen (DE)

(72) Inventors: Bernhard KREPPOLD, Fuerstenfeldbruck (DE); Benno SCHWEIGER, Muenchen (DE)

(21) Appl. No.: 17/049,054

(22) PCT Filed: Apr. 9, 2019
(86) PCT No.: PCT/EP2019/058968

§ 371 Date: Oct. 20, 2020

(30) Foreign Application Priority Data
Apr. 26, 2018 (DE) 10 2018 206 513.6

(51) Int. Cl. G01R 31/3835; B60L 53/62

(52) U.S. Cl. CPC G01R 31/3835; B60L 58/12; B60L 53/62

(57) ABSTRACT

A method for detecting an open-circuit voltage of a high-voltage store of an electrically drivable motor vehicle is provided. To increase the accuracy of an estimation of a state parameter of the high-voltage store, the high-voltage store is charged or discharged before a predetermined time until a measured state of charge is reached in which the high-voltage store is charged to a lesser extent than in a specified state of charge, the charging or discharging of the high-voltage store is interrupted for an interruption time period from the moment at which the measured state of charge is reached, and the open-circuit voltage is measured during the time period once a relaxation time period has elapsed, which starts with the interruption of the charging or discharging and is shorter than the interruption time period.

### BACKGROUND AND SUMMARY OF THE INVENTION

The invention relates to a method for detecting at least one open-circuit voltage value of a high-voltage store of an electrically driveable motor vehicle that is associated with a particular state of charge of the high-voltage store, wherein a time is predefined and the high-voltage store is able to be charged to the predefined state of charge before or up to the time.

The invention furthermore relates to a method for operating a high-voltage store of an electrically driveable motor vehicle, wherein at least one state parameter of the high-voltage store is determined taking into account a curve of an open-circuit voltage of the high-voltage store against a relative state of charge of the high-voltage store and is taken into account during operation of the high-voltage store.

The curve of the open-circuit voltage (OCV) against the (relative) state of charge (SOC) of a lithium-ion high-voltage store is critical for many functions in order to ascertain the state of the high-voltage store, such as for example for determining a capacitance or ascertaining the SOC. The OCV curve of the high-voltage store installed in a motor vehicle is conventionally measured during development on a test bench in complex processes and stored in the controller for the high-voltage store.

The OCV curve of a particular battery cell type of a high-voltage store depends on the electrode materials installed in this battery cell type and on the electrolytes that are used. The OCV curve may change as the aging of the battery cells increases. This circumstance is taken into consideration during the development by also measuring the OCV curves of battery cells subjected to shortened aging on the test bench and storing them in the controller.

Open-circuit voltage values are measured by creating a particular state of charge of the high-voltage store in a targeted manner and then measuring the open-circuit voltage after awaiting the relaxation time. Depending on the environmental conditions (temperature etc.), the relaxation time may last several hours.

Since Li-ion battery cells age as a result of various chemical processes in the respective battery cell, it is possible for the OCV curves of two different battery cells of the same type to change differently with increasing age. It is in particular not certain that the OCV curves of the battery cells subjected to shortened aging will exhibit an identical change with respect to battery cells that age during normal operation.

When charging a lithium-ion high-voltage store in an electrically driveable motor vehicle, when a predefined departure time is present, charging is at present able to be protracted as long as possible in order to ensure, through the charging, a high-voltage store that is already at a warm operating temperature immediately before the departure of the motor vehicle.

Due to the fact that only information from artificially aged battery cells is able to be used as OCV curve in the controller for a high-voltage store, in the event of deviating actual aging behavior, there may be increasing inaccuracies when ascertaining the state of the high-voltage store. For the client, this takes the form of a combination of different symptoms, specifically a jumpy remaining range, an excessively restricted range and, in the worst-case scenario, becoming stranded due to an overestimated capacity of the high-voltage store.

The inaccuracies are usually compensated by incorporating safety buffers for the estimation errors. By way of example, a high-voltage store is not completely discharged since the estimation of the state of charge of the high-voltage store could be inaccurate or could exhibit an unknown deviation. These inaccuracy margins reduce the range of the motor vehicle.

One object of the invention is to increase the accuracy of an estimation of at least one state parameter of a high-voltage store of an electrically driveable motor vehicle, in particular of an aged high-voltage store.

This object is achieved by the independent patent claims. Advantageous refinements are given in the dependent patent claims, the following description and the figures, wherein these refinements may each represent a further or advantageous aspect of the invention on their own or in a combination of at least two of these refinements with one another.

In accordance with a method according to the invention for detecting at least one open-circuit voltage value of a high-voltage store of an electrically driveable motor vehicle that is associated with a particular state of charge of the high-voltage store, a time of the motor vehicle is predefined and the high-voltage store is able to be charged to the predefined state of charge before or up to the time. The high-voltage store is additionally charged or discharged before the predefined time until reaching a predefined measurement state of charge in which the high-voltage store is charged less than in the predefined state of charge, the charging or discharging of the high-voltage store is interrupted for a period of predefined length after reaching the predefined measurement state of charge, and the open-circuit voltage value is measured during the period after a relaxation period of predefined length that is shorter than the predefined length of the period, beginning with the interruption of the charging or discharging, has elapsed.

According to the invention, the OCV curve of the high-voltage store may be measured in parts during a charging procedure or discharging procedure by detecting individual open-circuit voltage values of the high-voltage store according to the invention. This achieves a situation whereby the controller of the high-voltage store knows the current shape of the OCV curve of the high-voltage store installed in the motor vehicle. As a result, the accuracy of state estimation functions of the controller, in particular in the case of an aged high-voltage store, is increased. The increased accuracy of the state estimation functions of the controller allows a more plausible profile of state of charge estimations and makes it possible to display the range of the motor vehicle and to reduce inaccuracy margins and thus to increase the range of the motor vehicle.

According to the invention, a quiescent phase of a conventional charging procedure or discharging procedure at a predefined time, for example the departure time or the like, is used in order to approach particular SOC points (measurement states of charge) in a targeted manner and to measure the open-circuit voltage of the high-voltage store there. This is achieved by initially starting the charging procedure, or the discharging procedure for example when the high-voltage store is already completely charged, following connection to an electrical energy supply, with charging or discharging until the measurement state of charge of the high-voltage store is reached. When the measurement state of charge is reached, the charging procedure or discharging procedure is interrupted and the relaxation time of the high-voltage store is awaited. After the open-circuit voltage of the high-voltage store has been measured, the charging procedure may be continued or a charging procedure may be started until the high-voltage store reaches the predefined state of charge. The charging procedure is then ended.

The method may also be used to detect two or more open-circuit voltage values of the high-voltage store. To this end, the high-voltage store, which may be for example a traction battery of the electrically driveable motor vehicle, is connected to a battery controller that is configured so as to detect and evaluate open-circuit voltage values of the high-voltage store. The electrically driveable motor vehicle may be for example an electric vehicle or a hybrid electric vehicle, in particular a plug-in hybrid electric vehicle.

Since the open-circuit voltage value is detected at a particular state of charge of the high-voltage store, specifically the measurement state of charge, this open-circuit voltage value is associated unambiguously with the particular state of charge of the high-voltage store. The predefined time before which the high-voltage store is charged until reaching the predefined state of charge may be input into vehicle electronics via a human-machine interface, for example a touchscreen, and stored there in a manner able to be retrieved in order to be able to automatically begin the charging procedure in a timely manner before the predefined time. The relaxation period of the high-voltage store is that period that has to be awaited following charging or discharging of the high-voltage store for the high-voltage store to completely relax, wherein a battery chemistry of the high-voltage store is in a stable state after the relaxation period has elapsed.

The discharging of the high-voltage store in order to reach the measurement state of charge may be performed for example when using bidirectional charging in which it is possible to return electrical energy contained in the high-voltage store to a supply grid. If the high-voltage store is already completely charged following connection to the supply grid, the high-voltage store may initially be discharged, according to the invention, by feeding electrical energy into the supply grid until the measurement state of charge is reached. The high-voltage store may then be recharged until the predefined state of charge is reached.

The predefined state of charge that is generated before the predefined time is reached may be a maximum state of charge of the high-voltage store. As an alternative, the predefined state of charge may be less than 100%, for example 80%, of the maximum state of charge in order to reduce the consequences of aging.

In order to prompt a vehicle user to create states or boundary conditions, for example to perform a charging procedure with a departure time that is far in the future, in which the inventive measurement of the OCV curve is possible, the vehicle user may for example be given access to technical explanations. By way of example, an interactive display of the motor vehicle may be used to show the vehicle user the advantages afforded to him when he creates expedient boundary conditions. As an alternative or in addition, a vehicle user may for example receive more points when he creates the requested states or boundary conditions. These points may for example be compared with one another in a ranking list in social media portals in a kind of competition or converted for example into merchandise articles (ballpoint pens, beanie hats, etc.).

According to one advantageous refinement, at least two open-circuit voltage values that are associated with different states of charge of the high-voltage store are detected, wherein the high-voltage store is charged or discharged at the end of the period before the predefined time until reaching a predefined further measurement state of charge in which the high-voltage store is charged less than in the predefined state of charge and is charged more than in the measurement state of charge, the charging or discharging of the high-voltage store is interrupted for a further period of predefined length after reaching the predefined further measurement state of charge, and a further open-circuit voltage value is measured during the further period after a further relaxation period of predefined length that is shorter than the predefined length of the further period, beginning with the interruption of the charging or discharging, has elapsed. In particular when the predefined time is far enough in the future, starting from connection to an electrical energy supply, according to this refinement, two or more open-circuit voltage values of the high-voltage store may be measured during a single charging procedure or discharging procedure. The entire OCV curve of the high-voltage store installed in the motor vehicle is thus able to be measured over a plurality of charging procedures or discharging procedures.

According to a further advantageous refinement, the open-circuit voltage value is detected for the state of charge of the high-voltage store with respect to which a previous detection of the open-circuit voltage value, out of at least two previous detections of open-circuit voltage values, is furthest in the past. The greatest possible up-to-dateness of the open-circuit voltage values or of an OCV curve formed therefrom is thereby able to be guaranteed.

According to a further advantageous refinement, following connection of a charger, connected to the high-voltage store, to a supply grid, a start time for the charging or discharging of the high-voltage store is determined taking into account a current state of charge of the high-voltage store. If for example the charger is connected to the supply grid in the evening, it is sufficient for the high-voltage store to have been conferred the predefined state of charge the next morning.

A further advantageous refinement makes provision for a planned departure time of the motor vehicle to be predefined as the time. This makes it possible to provide a high-voltage store at a warm operating temperature at the departure time.

In accordance with a method according to the invention for operating a high-voltage store of an electrically driveable motor vehicle, at least one state parameter of the high-voltage store is determined taking into account a curve of an open-circuit voltage of the high-voltage store against a relative state of charge of the high-voltage store and taken into account during operation of the high-voltage store, wherein at least one open-circuit voltage value of the curve is determined using the method according to one of the abovementioned refinements or a combination of at least two of these refinements with one another.

This method accordingly links the advantages mentioned above with respect to the detection method. The state parameter may for example be a storage capacity of the high-voltage store or the like.

According to one advantageous refinement, at least one detected open-circuit voltage value is transmitted wirelessly, together with the measurement state of charge associated therewith, to a central data processing unit that is remote from the vehicle, that compares the open-circuit voltage value with an expected voltage value for the measurement state of charge and transmits an information signal to the motor vehicle on the basis of a result of this comparison when a deviation between the open-circuit voltage value and the expected voltage value exceeds a predefined extent. The measurements of the open-circuit voltage values of high-voltage stores of electrically driveable motor vehicles are thereby able to be exchanged via a back-end link or the like with the central data processing unit. By comparing changes of OCV curves from different motor vehicles with the expected values, the onset of defects is already able to be recognized in advance and appropriate measures, such as transmitting the information signal to the respective motor vehicle, may be taken. The vehicle user may use the information signal to decide whether to take a measure that prevents a defect or to allow such a measure to be taken.

Further details, features and advantages of the invention will become apparent from the following description and the figures, in which:

### BRIEF DESCRIPTION OF THE DRAWINGS

FIG. 1 shows a graph of one exemplary embodiment of an open-circuit voltage curve of a high-voltage store; and

FIG. 2 shows a graph regarding a charging procedure according to one exemplary embodiment of a method according to the invention.

### DETAILED DESCRIPTION OF THE DRAWINGS

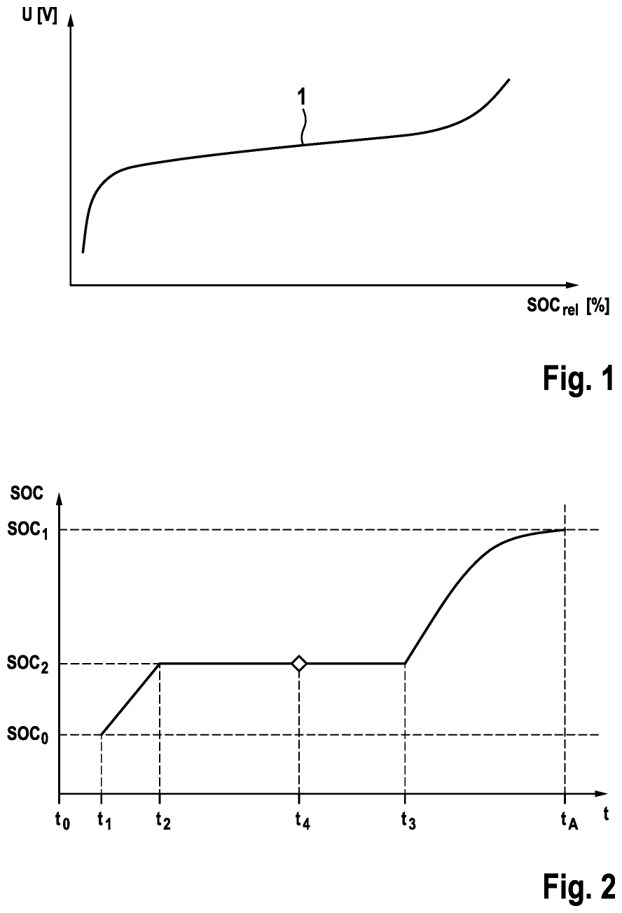

FIG. 1 shows a graph of one exemplary embodiment of an open-circuit voltage curve 1 of a high-voltage store, not shown. The open-circuit voltage U of the high-voltage store is plotted against the relative state of charge SOCᵣₑₗ. This profile of the open-circuit voltage curve 1 is typical for a high-voltage store. The open-circuit voltage increases as the charging of the high-voltage store increases.

FIG. 2 shows a graph regarding a charging procedure according to one exemplary embodiment of a method according to the invention for detecting at least one open-circuit voltage value of a high-voltage store, not shown, of an electrically driveable motor vehicle, not shown, that is associated with a particular state of charge of the high-voltage store. The state of charge SOC is plotted against time t.

A time t_{A} is initially predefined in the form of a departure time of the motor vehicle. At the time t₀, the motor vehicle is connected to an electrical energy supply, not shown. At this time t₀, the high-voltage store has an initial state of charge SOC₀. The high-voltage store is charged before the predefined time t_{A} until reaching a predefined state of charge SOC₁, in which the high-voltage store is 80% charged.

The high-voltage store is charged, in a period from t₁ to t₂ before the predefined time t_{A}, until reaching a predefined measurement state of charge SOC₂ in which the high-voltage store is charged less than in the predefined state of charge SOC₁. After reaching the predefined measurement state of charge SOC₂ or after the time t₂, the charging of the high-voltage store is interrupted for a period of predefined length that begins at the time t₂ and ends at a time t₃. During this period, the open-circuit voltage value is measured after a relaxation period of predefined length t₄-t₂ that is shorter than the predefined length t₃-t₂ of the period, beginning with the interruption of the charging or at the time t₂, has elapsed. After the time t₃, the charging procedure is continued until the predefined state of charge SOC₁ is reached. The charging procedure is then ended. The open-circuit voltage value may be detected for the state of charge SOC of the high-voltage store with respect to which a previous detection of the open-circuit voltage value, out of at least two previous detections of open-circuit voltage values, is furthest in the past.

### LIST OF REFERENCE SIGNS

1 open-circuit voltage curve
SOC state of charge
SOC₀ initial state of charge
SOC₁ maximum state of charge
SOC₂ measurement state of charge
SOCᵣₑₗ relative state of charge
t time
t_{A} departure time
t₀ time (connection to energy supply)
t₁ time (beginning of charging procedure)
t₂ time (interruption of charging procedure)
t₃ time (end of period)
t₄ time (open-circuit voltage measurement)
U open-circuit voltage

1.-7. (canceled)

8. A method for detecting an open-circuit voltage value of a high-voltage store of an electrically driveable motor vehicle that is associated with a state of charge of the high-voltage store, wherein the high-voltage store is chargeable to a first state of charge before or up to a predetermined time, comprising:
charging or discharging the high-voltage store before the predetermined time until reaching a second state of charge in which the high-voltage store is charged less than in the first state of charge;
interrupting the charging or discharging of the high-voltage store for a predetermined period of time after reaching the second state of charge; and
measuring the open-circuit voltage value during a period of time, after a first relaxation period of time has elapsed, that is shorter than the predetermined period of time beginning with the interrupting of the charging or discharging.

9. The method according to claim 8, wherein at least two open-circuit voltage values that are associated with different states of charge of the high-voltage store are measured, wherein the high-voltage store is charged or discharged at an end of the predetermined period of time until reaching a third state of charge in which the high-voltage store is charged less than in the first state of charge and is charged more than in the second state of charge, the charging or discharging of the high-voltage store is interrupted for a second period of time after reaching the third state of charge, and a further open-circuit voltage value is measured during the second period of time after a second relaxation period of time has elapsed that is shorter than the second period of time, beginning with the interrupting of the charging or discharging.

10. The method according to claim 8, wherein the open-circuit voltage value is detected for the state of charge of the high-voltage store with respect to which a previous detection of the open-circuit voltage value, out of at least two previous detections of open-circuit voltage values, is furthest in the past.

11. The method according to claim 8, wherein, following connection of a charger to the high-voltage store, a start time for the charging or discharging of the high-voltage store is determined taking into account a current state of charge (SOC) of the high-voltage store.

12. The method according to claim 8, wherein the predetermined time is a planned departure time of the electrically driveable motor vehicle.

13. A method for operating a high-voltage store of an electrically driveable motor vehicle, wherein a state parameter of the high-voltage store is determined based on a curve of an open-circuit voltage of the high-voltage store versus a relative state of charge of the high-voltage store and the state parameter is taken into account during operation of the high-voltage store, wherein an open-circuit voltage value of the curve is determined using the method according to claim 8.

14. The method according to claim 13, wherein the open-circuit voltage value is transmitted, together with the second state of charge associated therewith, to a central data processing unit that is remote from the electrically driveable motor vehicle, that compares the open-circuit voltage value with an expected voltage value for the second state of charge and transmits an information signal to the electrically driveable motor vehicle when a deviation between the open-circuit voltage value and the expected voltage value exceeds a predetermined value.
